(19) United States
(12) Patent Application Publication
(10) Pub. No.: US 2011/0283153 A1
(43) Pub. Date: Nov. 17, 2011

(54) TEST APPARATUS, TEST MODULE AND TEST METHOD

(75) Inventor: Akio MORIKAWA, Saitama (JP)

(73) Assignee: ADVANTEST CORPORATION, Tokyo (JP)

(21) Appl. No.: 13/038,343

(22) Filed: Mar. 1, 2011

Related U.S. Application Data
(63) Continuation of application No. PCT/JP2009/004734, filed on Sep. 18, 2009.

(30) Foreign Application Priority Data
Sep. 26, 2008 (JP) 2008-247690

(51) Int. Cl. G11C 29/00; G06F 11/00

(52) U.S. Cl. 714/719; 714/E11.02

(57) ABSTRACT

A test module comprising a compression information storage section that stores a plurality of pieces of compression information that each associate a pattern sequence with a piece of pattern sequence identification information; a basic pattern storage section that stores, as a group of basic patterns, a plurality of pieces of pattern sequence data that each include the pattern sequence or the pattern sequence identification information in association with a command; an instruction information storage section that stores instruction information indicating a processing order for the basic patterns; a selecting section that selects, from among the pieces of compression information stored in the compression information storage section, compression information to be used for the basic pattern to be processed according to the processing order indicated by the instruction information; a basic pattern reading section that reads, from the basic pattern storage section, the pattern sequence data included in the basic patterns to be processed; and a pattern sequence reading section that, when the pattern sequence identification information is included in the pattern sequence data read by the basic pattern reading section, references the compression information selected by the selecting section and reads the pattern sequence corresponding to the pattern sequence identification information.

### BACKGROUND

1. Technical Field

The present invention relates to a test module, a test apparatus, and a test method. In particular, the present invention relates to a test module, a test apparatus, and a test method for compressing and storing a test program used to test a device under test.

2. Related Art

The test apparatus tests a device under test (DUT), which is a testing target, based on a test program. The test program includes, for each command cycle, a command to be executed by the test apparatus and a test pattern to be output to each terminal of the device under test or an expected value pattern to be compared with an output pattern output from each terminal of the device under test.

Conventionally, in order to decrease the data amount of the test program, the test apparatus compresses the test program using repeating commands. For example, an IDXI command can be executed as a repeat command to repeatedly output the same test pattern to each terminal of the DUT the number of times designated by an operand. In other words, when the same pattern is used in series in a plurality of command cycles for every terminal in a conventional test apparatus, the size of the test program is decreased by using the repeat command.

Patent Document 1, for example, discloses a test apparatus that stores in a test pattern memory, independently for each command, a test mode test pattern sequence or a normal mode test pattern sequence. In this way, the test apparatus can store, in a test pattern memory, a test pattern sequence having a format suitable for the operational mode of the DUT, thereby effectively compressing the test program.

### Patent Document 1: Japanese Patent Application Publication No. 2006-58251

However, the increased speed of electronic devices in recent years has also increased the transmission speed of signals input to and output from electronic devices. To test such electronic devices, a test apparatus is desired that generates expected value patterns or test patterns more quickly.

It is difficult to significantly improve the capability of a test apparatus by shortening the command cycles during which the test program is performed. Therefore, one strategy is to realize a test apparatus that generates patterns at high speed while executing commands at relatively low speed, by supplying a plurality of test patterns or expected value patterns in one command cycle.

When a compression format using repeating commands is utilized by the test apparatus, compression is possible only when the exact same pattern sequence is repeatedly used in a plurality of command cycles for all of the terminals, and compression cannot be achieved if a portion of the pattern sequence is different. Therefore, simply utilizing a compression format that uses repeating commands does not achieve optimal compression efficiency, and there might not be enough memory space to store the test program.

### SUMMARY

Therefore, it is an object of an aspect of the innovations herein to provide a test module, a test apparatus, and a test method, which are capable of overcoming the above drawbacks accompanying the related art. The above and other objects can be achieved by combinations described in the independent claims. The dependent claims define further advantageous and exemplary combinations of the innovations herein.

According to a first aspect related to the innovations herein, provided is a test module comprising a compression information storage section that stores a plurality of pieces of compression information that each associate a pattern sequence with a piece of pattern sequence identification information identifying the pattern sequence; a basic pattern storage section that stores, as a group of basic patterns, a plurality of pieces of pattern sequence data that each include the pattern sequence or the pattern sequence identification information in association with a command; an instruction information storage section that stores instruction information indicating a processing order for the basic patterns; a selecting section that selects, from among the pieces of compression information stored in the compression information storage section, compression information to be used for the basic pattern to be processed according to the processing order indicated by the instruction information; a basic pattern reading section that reads, from the basic pattern storage section, the pattern sequence data included in the basic patterns to be processed; a pattern sequence reading section that, when the pattern sequence identification information is included in the pattern sequence data read by the basic pattern reading section, references the compression information selected by the selecting section and reads the pattern sequence corresponding to the pattern sequence identification information; and a pattern output section that outputs the pattern sequence corresponding to the pattern sequence identification information read by the pattern sequence reading section or the pattern sequence included in the pattern sequence data read by the basic pattern reading section.

The test module may further comprising a basic pattern information storage section that stores, in association with each basic pattern, compression information identification information identifying compression information to be used for processing the basic pattern. The selecting section may reference the compression information identification information to select the compression information. The compression information storage section may store the compression information further including repetition information that designates the number of times each pattern sequence is repeated, and the pattern output section may repeatedly output each pattern sequence according to the number of repetitions designated by the repetition information. The compression information storage section may store, as each pattern sequence, the compression information including a desired pattern sequence that is designated for each piece of compression information or a predefined pattern sequence determined in advance. The compression information storage section may include a plurality of the desired pattern sequences as the pattern sequences and stores, as the repetition information designating the number of desired pattern sequences, a single piece of pattern sequence identification information identifying the entirety of the desired pattern sequences, and the pattern output section may output the number of desired pattern sequences designated by the repetition information.

The compression information storage section may store, as the compression information, the pattern sequence and the pattern sequence identification information for each input or output channel, and the pattern output section may output the pattern sequence for each channel. The compression information storage section may store high-speed mode pattern sequences or low-speed mode pattern sequences as the pattern sequences and store, as the pattern sequence identification information, pattern identification information indicating whether the corresponding pattern sequence is a high-speed mode pattern sequence or a low-speed mode pattern sequence. The compression information storage section may store the high-speed mode pattern sequences as the pattern sequences included in the compression information and store, as the pattern sequence identification information, short-bit pattern sequence identification information that can designate one address space or long-bit pattern sequence identification information that can designate an address space larger than the one address space; a frequent predefined pattern sequence that is determined in advance and used frequently may be allocated as a pattern sequence identified by the short-bit pattern sequence identification information; and an infrequent predefined pattern sequence that is determined in advance and used less frequently than the frequent predefined pattern sequence may be allocated as a pattern sequence identified by the long-bit pattern sequence identification information. The compression information storage section may store a desired pattern sequence that is determined for each piece of compression information and is a high-speed mode pattern sequence as all of the pattern sequences included in the compression information, and store null data as the pattern sequence identification information.

According to a second aspect related to the innovations herein, provided is a test apparatus comprising a compression information storage section that stores a plurality of pieces of compression information that each associate a pattern sequence with a piece of pattern sequence identification information identifying the pattern sequence; a basic pattern storage section that stores, as a group of basic patterns, a plurality of pieces of pattern sequence data that each include the pattern sequence of the pattern sequence identification information in association with a command; an instruction information storage section that stores instruction information indicating a processing order for the basic patterns; a selecting section that selects, from among the pieces of compression information stored in the compression information storage section, compression information to be used for the basic patterns to be processed according to the processing order indicated by the instruction information; a basic pattern reading section that reads, from the basic pattern storage section, the pattern sequence data included in the basic patterns to be processed; a pattern sequence reading section that, when the pattern sequence identification information is included in the pattern sequence data read by the basic pattern reading section, references the compression information selected by the selecting section and reads the pattern sequence corresponding to the pattern sequence identification information; and a pattern output section that outputs the pattern sequence corresponding to the pattern sequence identification information read by the pattern sequence reading section or the pattern sequence included in the pattern sequence data read by the basic pattern reading section.

According to a third aspect related to the innovations herein, provided is a test method comprising compression information storage of storing a plurality of pieces of compression information that each associate a pattern sequence with a piece of pattern sequence identification information identifying the pattern sequence; basic pattern storage of storing, as a group of basic patterns, a plurality of pieces of pattern sequence data that each include the pattern sequence of the pattern sequence identification information in association with a command; instruction information storage of storing instruction information indicating a processing order for the basic patterns; selecting, from among the pieces of compression information stored during the compression information storage, compression information to be used for the basic patterns to be processed according to the processing order indicated by the instruction information; basic pattern reading of reading the pattern sequence data included in the basic patterns to be processed; pattern sequence reading of, when the pattern sequence identification information is included in the pattern sequence data read during the basic pattern reading, referencing the selected compression information and reading the pattern sequence corresponding to the pattern sequence identification information; and pattern output of outputting the pattern sequence corresponding to the pattern sequence identification information read during the pattern sequence reading or the pattern sequence included in the pattern sequence data read during the basic pattern reading.

The summary clause does not necessarily describe all necessary features of the embodiments of the present invention. The present invention may also be a sub-combination of the features described above.

### BRIEF DESCRIPTION OF THE DRAWINGS

FIG. 1 shows an exemplary configuration of a test module 10 according to an embodiment of the present invention.

FIG. 2 shows a configuration of the sequential pattern generating section 142 and the sequential pattern generating section 146 according to the present embodiment.

FIG. 3 shows exemplary compressed information according to the present embodiment.

FIG. 4 shows an exemplary test program according to the present embodiment.

FIG. 5 shows a compression format of a test program according to the present embodiment.

FIG. 6 shows exemplary pattern compression information according to a modification of the present embodiment.

FIG. 7 shows exemplary pattern compression information according to another modification of the present embodiment.

FIG. 8 shows exemplary pattern compression information according to another modification of the present embodiment.

FIG. 9 shows exemplary pattern compression information according to another modification of the present embodiment.

FIG. 10 shows exemplary pattern compression information according to another modification of the present embodiment.

### DESCRIPTION OF EXEMPLARY EMBODIMENTS

Hereinafter, some embodiments of the present invention will be described. The embodiments do not limit the invention according to the claims, and all the combinations of the features described in the embodiments are not necessarily essential to means provided by aspects of the invention.

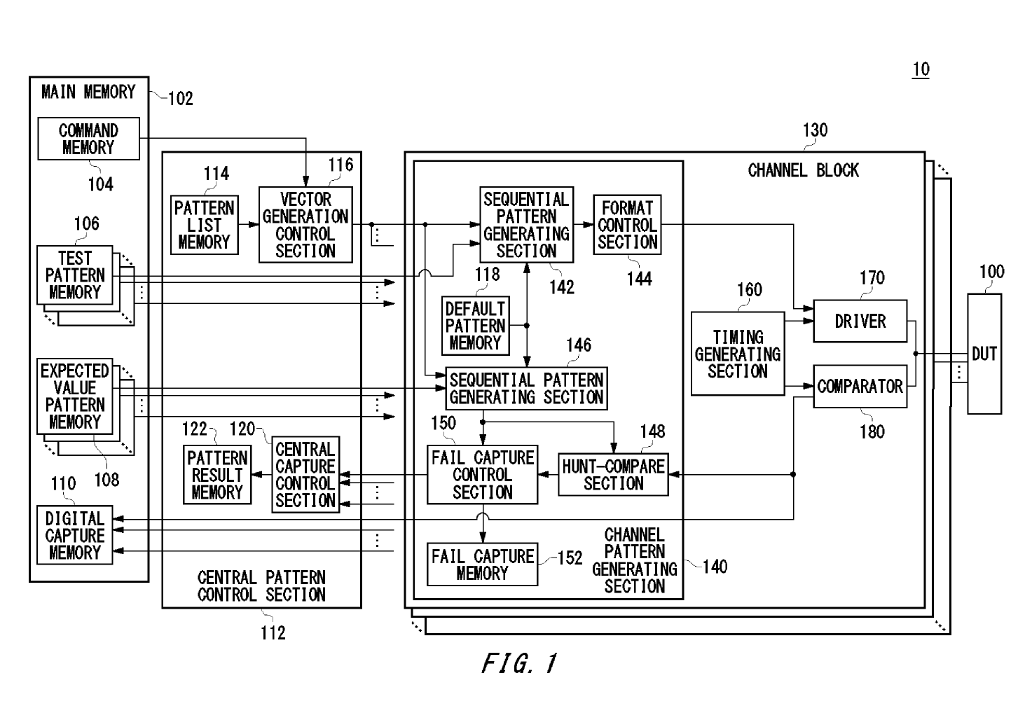

FIG. 1 shows an exemplary configuration of a test module 10 according to an embodiment of the present invention. The test module 10 may be used in a test apparatus that tests a DUT 100 having one or more terminals. The test module 10 includes a main memory 102, a central pattern control section 112, and a plurality of channel blocks 130.

The main memory 102 stores a test program for the DUT 100 and records output patterns output by the DUT 100 as a result of the test program being performed. The main memory 102 includes a command memory 104, a plurality of test pattern memories 106, a plurality of expected value pattern memories 108, and a digital capture memory 110. The command memory 104 stores instructions contained in a test program.

The test pattern memory 106 may be an example of a basic pattern storage section. The test pattern memory 106 stores, as one group of basic patterns, a plurality of pieces of pattern sequence data that include pattern sequences or pattern sequence identification information in association with commands. A test pattern memory 106 is provided to correspond to each terminal of the DUT 100, and each test pattern memory 106 stores a test pattern sequence used during a command cycle period in which commands are performed for the terminal. Here, the test pattern sequence may be an example of a pattern sequence. For example, if the test module 10 generates a signal with 32 bits for each command cycle and outputs this signal to the DUT 100, the test pattern memory 106 may store, in association with each command, a test pattern sequence with 32 test patterns corresponding to the signal with 32 bits output during one command cycle period.

The expected value pattern memory 108 may be an example of a basic pattern storage section. The expected value pattern memory 108 stores, as a group of basic patterns, a plurality of pieces of pattern data that include pattern sequences or pattern sequence identification information in association with commands. An expected value pattern memory 108 is provided to correspond to each terminal of the DUT 100, and each expected value pattern memory 108 stores an expected value pattern sequence used during a command cycle period in which commands are performed for the terminal. The expected value pattern sequence may be an example of a pattern sequence, and includes a plurality of expected value patterns that are to be sequentially compared to the plurality of output patterns sequentially output from terminals of the DUT 100 during the command cycle period. The digital capture memory 110 stores the output patterns output by the DUT 100 as a result of the test program being executed.

The command memory 104, the test pattern memories 106, the expected value pattern memories 108, and/or the digital capture memory 110 may be independently provided in separate modules forming the main memory 102, or may be provide as different storage regions within the same memory module.

The central pattern control section 112 is connected to the main memory 102 and a plurality of channel blocks 130, and performs a common process for each terminal of the DUT 100. The central pattern control section 112 includes a pattern list memory 114, a vector generation control section 116, a central capture control section 120, and a pattern result memory 122.

The pattern list memory 114 may be an example of an instruction information storage section. The pattern list memory 114 stores instruction information that designates the processing order of the basic patterns. For a main routine or each of a plurality of subroutines of the test program, the pattern list memory 114 stores start/end addresses of the routine in the command memory 104, stores the start address of the test pattern in the test pattern memory 106, and stores the start address of the expected value pattern in the expected value pattern memory 108, for example.

The vector generation control section 116 may be an example of a command executing section, and sequentially executes the commands contained in the test program of the DUT 100 in each command cycle. More specifically, for each routine, the vector generation control section 116 sequentially reads the commands from the start address to the end address from the pattern list memory 114 and sequentially executes these commands.

The central capture control section 120 receives a pass/fail judgment result for each terminal of the DUT 100 from the channel blocks 130, and calculates the pass/fail judgment result of the DUT 100 for each routine. The pattern result memory 122 stores the pass/fail judgment result of the DUT 100 for each routine.

A channel block 130 is provided to correspond to each terminal of the DUT 100. Each channel block 130 includes a channel pattern generating section 140, a timing generating section 160, a driver 170, and a comparator 180.

The channel pattern generating section 140 generates a test pattern sequence or an expected value pattern sequence used when testing the terminal, and compares the output pattern sequence of the DUT 100 to the expected value pattern sequence. The channel pattern generating section 140 includes a predefined pattern memory 118, a sequential pattern generating section 142, a format control section 144, a sequential pattern generating section 1146, a hunt/compare section 148, a fail capture control section 150, and a fail capture memory 152.

The predefined pattern memory 118 may be an example of a compression information storage section. The predefined pattern memory 118 stores a plurality of pieces of compression information that associate pattern sequences with pattern sequence identification information identifying the pattern sequences. The predefined pattern memory 118 stores test pattern sequences and/or expected value pattern sequence, i.e. predefined pattern sequences that are set in advance from among the pattern sequences, in association with predefined pattern identification information that identifies the predefined pattern sequences. The predefined pattern identification information may be an example of pattern sequence identification information. The test pattern memory 106 and/or the expected value pattern memory 108 store the predefined pattern identification information of pattern sequences identical to the predefined pattern sequences in place of the pattern sequences themselves.

The sequential pattern generating section 142 receives, from the vector generation control section 116, the start address of the test pattern sequence to be output in correspondence with the executed routine. The sequential pattern generating section 142 sequentially reads the test pattern sequence from the test pattern memory 106 beginning with the start address, in correspondence with each command cycle, and sequentially outputs the read test pattern sequence to the format control section 144. The format control section 144 functions together with the driver 170 as a test pattern output section in the present embodiment, and converts the test pattern sequences to a format for controlling the driver 170.

The sequential pattern generating section 146 receives the start address of the expected value pattern sequence from the vector generation control section 116, in correspondence with the executed routine. The sequential pattern generating section 146 sequentially reads the expected value patterns from the expected value pattern memory 108 beginning with the start address, in correspondence with each command cycle, and sequentially outputs the read expected value patterns to the hunt/compare section 148 and the fail capture control section 150. The hunt/compare section 148 is an example of an expected value comparing section in the present embodiment. The hunt/compare section 148 receives the output pattern sequence output by the DUT 100 through the comparator 180, and compares the output pattern sequence to the expected value pattern sequence. Here, the hunt/compare section 148 may have a hunt function that begins the comparison with the expected value pattern sequence on a condition that a specific header pattern is output from the DUT 100, for output pattern sequences that are output from the DUT 100 with non-uniform timing.

The fail capture control section 150 receives, from the hunt/compare section 148, information indicating whether the output pattern sequence of the DUT 100 matches the expected value pattern sequence, and generates a pass/fail judgment result for the corresponding terminal of the DUT 100. The fail capture memory 152 stores fail information that contains results of the hunt process by the hunt/compare section 148, values of the output patterns that do not match the expected values, or the like.

The timing generating section 160 generates the timing at which the driver 170 outputs each test pattern in the test pattern sequence and the timing at which the comparator 180 acquires the output patterns of the DUT 100. The driver 170 functions together with the format control section 144 as a test pattern output section in the present embodiment, and outputs each test pattern from the format control section 144 in the channel pattern generating section 140 to the DUT 100 at the timing designated by the timing generating section 160. The comparator 180 acquires the output patterns output form the corresponding terminal of the DUT 100 at the timing designated by the timing generating section 160, and supplies the output patterns to the digital capture memory 110 and the hunt/compare section 148 in the channel block 130.

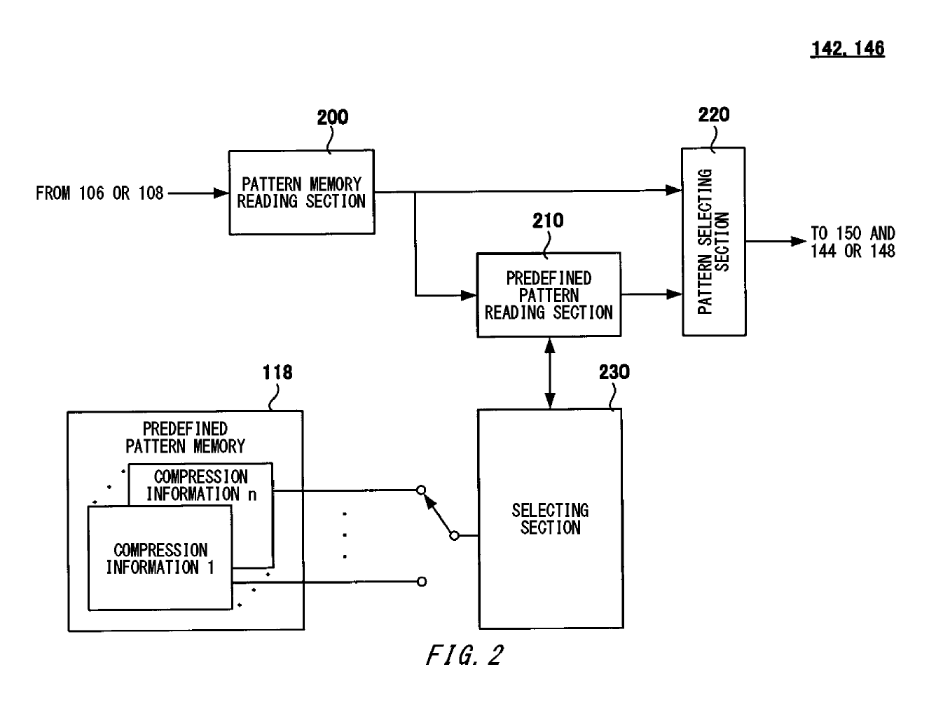

FIG. 2 shows a configuration of the sequential pattern generating section 142 and the sequential pattern generating section 146 according to the present embodiment, along with the predefined pattern memory 118. The sequential pattern generating section 142 includes a pattern memory reading section 200, a predefined pattern reading section 210, a pattern selecting section 220, and a selecting section 230.

The pattern memory reading section 200 may be an example of a basic pattern reading section. The pattern memory reading section 200 reads, from the test pattern memory 106 or the expected value pattern memory 108, pattern sequence data contained in the basic pattern of a target for processing. When the test module 10 executes a command, the pattern memory reading section 200 reads pattern sequence data, i.e. the test pattern sequence of the predefined pattern identification information, stored in the test pattern memory 106 in association with this command.

The selecting section 230 selects compression information that is used for the basic pattern of a processing target indicated by a pattern list, which is an example of instruction information, from among a plurality of pieces of compression information stored in the predefined pattern memory 118, which is an example of a compression information storage section. The predefined pattern memory 118 includes a plurality of pieces of compression information from 1 to n. The selecting section 230 can select one of the pieces of compression information for each pattern. In the test module 10 of the present embodiment, the inclusion of the selecting section 230 enables the compression information to be switched for each basic pattern. The test module 10 can include a basic pattern information storage section that stores compression information identification information, which identifies the compression information to be used when processing a basic pattern, in association with each basic pattern. The selecting section 230 can reference the compression information identification information to select the selection compression selection information.

The predefined pattern reading section 210 may be an example of a pattern sequence reading section. When predefined pattern sequence identification information, which may be an example of pattern sequence identification information, is contained in the pattern sequence data read by the pattern memory reading section 200, the predefined pattern reading section 210 references the compression information selected by the selecting section 230 and reads the predefined pattern sequence corresponding to the predefined pattern sequence identification information. In this way, the predefined pattern reading section 210 converts the predefined pattern identification information into a corresponding predefined pattern sequence.

The pattern selecting section 220 may be an example of a pattern output section. The pattern selecting section 220 outputs a pattern sequence corresponding to the pattern sequence identification information read by the pattern sequence reading section or the pattern sequence included in the pattern sequence data read by the pattern memory reading section 200. The pattern selecting section 220 selects a predefined pattern sequence read from the predefined pattern memory 118 by the predefined pattern reading section 210 or a test pattern read from the test pattern memory 106 by the pattern memory reading section 200, in correspondence with one command in a command cycle period during which this command is executed. The pattern selecting section 220 outputs the selected pattern sequence to the format control section 144. More specifically, the pattern selecting section 220 determines whether the predefined pattern identification information or the test pattern sequence associated with the one command is read from the test pattern memory 106 and, when the test pattern sequence is read, outputs the test pattern sequence read from the pattern memory reading section 200 to the format control section 144. On the other hand, when the predetermined pattern identification information is read, the pattern selecting section 220 outputs the predefined pattern sequence output from the predefined pattern reading section 210 to the format control section 144. Upon receiving this predefined pattern identification information or test pattern sequence, the format control section 144 and the driver 170, which are an example of the test pattern output section of the present embodiment, output the test pattern or the predefined pattern sequence selected by the pattern selecting section 220 to a terminal of the DUT 100 connected to the driver 170.

The sequential pattern generating section 146 adopts the same function and configuration as the sequential pattern generating section 142, and therefore a separate description is omitted. Instead of the sequential pattern generating section 142 and the sequential pattern generating section 146 being provided separately, the channel pattern generating section 140 may include a sequential pattern generating section that has the functions of both the sequential pattern generating section 142 and the sequential pattern generating section 146.

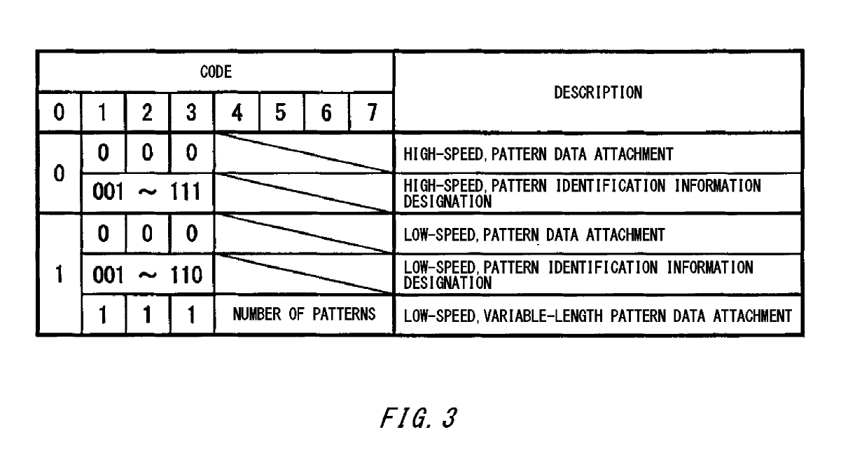

FIG. 3 shows exemplary compressed information according to the present embodiment. In the present embodiment, the test pattern memory 106 and/or the expected value pattern memory 108 store, in association with each command, a piece of test pattern compression information and/or a piece of expected value pattern compression information (referred to hereinafter as “pattern compression information”), in order to determine whether a pattern sequence or predefined pattern identification information is stored. The following is a description of an exemplary code format for the pattern compression information, with reference to FIG. 3. As described above, the present embodiment includes a plurality of pieces of pattern compression information.

In the pattern compression information of the present embodiment, the 0-th bit is used as vector length information that designates the vector length of the pattern sequence used in one command cycle period. The test module 10 of the present embodiment has a plurality of operational modes using pattern sequences with different vector lengths in one command cycle period. For example, the test module 10 may have a first operational mode, e.g. a high-speed mode, for testing using a test pattern sequence or an expected value pattern sequence including 32 patterns, and a second operational mode, e.g. a low-speed mode, for testing using a test pattern sequence or an expected value pattern sequence including 1 pattern. The vector length information designates whether the pattern sequence of the corresponding pattern compression information is handled as a pattern sequence in the first operational mode or the second operational mode.

In the first operational mode, i.e. when the 0-th bit has a value of 0, pattern compression information having a predetermined specified value, e.g. a value of 000 for the first bit to the third bit, indicates that the pattern sequence is stored. In this case, the test pattern memory 106 and/or the expected value pattern memory 108 stores, in association with the command, the pattern sequence of the first operational mode, i.e. a pattern sequence including 32 patterns, together with the pattern compression information.

In the first operational mode, pattern compression information that does not have a predetermined specified value, e.g. pattern compression information with any value from 001 to 111 for the first bit to the third bit, is used as predefined pattern identification information. In this case, the test pattern memory 106 and/or the expected value pattern memory 108 stores the pattern compression information in association with the command, and does not attach the pattern sequence.

In the first operational mode, the test module 10 performs the following processes. First, when a command is executed, the pattern memory reading section 200 reads the pattern identification information from the test pattern memory 106 or the expected value pattern memory 108, and also reads the pattern sequence if the pattern compression information has the specified value, i.e. if the first to third bits thereof have a value of 0000. Next, if the pattern compression information is not the specified value, the predefined pattern reading section 210 reads the predefined pattern sequence stored in the predefined pattern memory 118 in association with the pattern compression information. If the pattern compression information is the specified value, the pattern selecting section 220 selects the pattern sequence output by the pattern memory reading section 200, and if the pattern compression information is not the specified value, the pattern selecting section 220 selects the predefined pattern sequence output by the predefined pattern reading section 210.

In the second operational mode, i.e. when the 0-th bit has a value of 1, pattern compression information having a predetermined specified value, e.g. a value of 000 or 111 for the first bit to the third bit, indicates that a pattern sequence is stored. When the first to third bits are 000, the test pattern memory 106 and/or the expected value pattern memory 108 stores the pattern sequence of the second operational mode, which is a pattern sequence in which one pattern corresponds to one command, together with the pattern compression information in association with 16 commands executed during 16 continuous command cycles. When the first to third bits are 111, the test pattern memory 106 and/or the expected value pattern memory 108 stores, in association with a number of commands equal to the number of patterns executed during the command cycle period corresponding to the number of patterns designated by the fourth to seventh bits of the pattern compression information, the pattern sequence of the second operational mode, which has a length equal to the number of patterns, together with the pattern compression information. By changing the fourth to seventh bits, the test pattern memory 106 and/or the expected value pattern memory 108 can store patterns with variable lengths corresponding to one piece of pattern compression information.

In the second operational mode, pattern compression information that is not the specified value, e.g. pattern compression information in which the first to third bits have a value from 001 to 110, is used as the predefined pattern identification information. In this case, the test pattern memory 106 and/or the expected value pattern memory 108 stores the pattern compression information in association with the command, and does not attach the pattern sequence.

In the second operational mode, the test module 10 performs the following processes. First, when a command is executed, the pattern memory reading section 200 reads the pattern identification information from the test pattern memory 106 or the expected value pattern memory 108, and also reads the pattern sequence if the pattern compression information has a specified value, i.e. if the 0-th to third bits thereof have a value of 1000 or 1111. Next, if the pattern compression information is not a specified value, the predefined pattern reading section 210 reads the predefined pattern sequence stored in the predefined pattern memory 118 in association with the pattern compression information. If the pattern compression information is a specified value, the pattern selecting section 220 selects the pattern sequence output by the pattern memory reading section 200, and if the pattern compression information is not a specified value, the pattern selecting section 220 selects the predefined pattern sequence output by the predefined pattern reading section 210. In the second operational mode, each pattern in the selected pattern sequence is sequentially used over a plurality of command cycle periods from the one executed command.

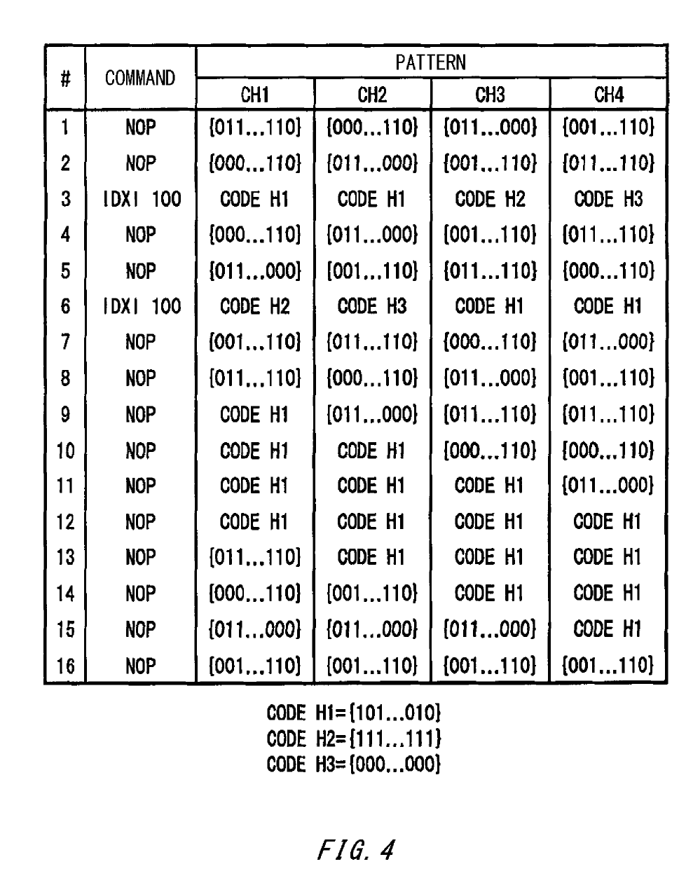

FIG. 4 shows an exemplary test program according to the present embodiment. The test program shown in FIG. 4 includes a plurality of commands to be executed sequentially and a test pattern sequence to be output to the DUT 100 during a test cycle period in which the commands associated with the terminals CH1 to CH4 are executed. The command memory 104 stores each of the commands shown in FIG. 4. Each test pattern memory 106 stores, in association with each command, a test pattern sequence output during the command cycle period in which the command is executed or pattern compression information used as predefined pattern sequence identification information for identifying a predefined pattern output during the command cycle period.

For example, in association with the command “NOP” in the first line, the test pattern memory 106 of the terminal CH1 may store the test pattern sequence {011 . . . 110}, the test pattern memory 106 of the terminal CH2 may store the test pattern sequence {000 . . . 110}, the test pattern memory 106 of the terminal CH3 may store the test pattern sequence {011 . . . 000}, and the test pattern memory 106 of the terminal CH4 may store the test pattern sequence {001 . . . 110}. More specifically, each test pattern memory 106 stores the test pattern sequence in a group with pattern compression information of a specified value, e.g. a value of 0000 in the 0-th to third bits thereof, and the pattern sequence attached to this pattern compression information.

As another example, in association with the command “IDXI 100” in the third line, the test pattern memories 106 of the terminals CH1 and CH2 may each store the pattern compression information CODEH1 having a value of 0001 for the 0-th to third bits thereof, i.e. a value other than the specified value, the test pattern memory 106 of the terminal CH3 may store the pattern compression information CODEH2 having a value of 0010 for the 0-th to third bits thereof, i.e. a value other than the specified value, and the test pattern memory 106 of the terminal CH4 may store the pattern compression information CODEH3 having a value of 0011 for the 0-th to third bits thereof, i.e. a value other than the specified value. In this way, the test pattern memories 106 can store different predefined pattern identification information respectively for the terminals in association with the same command.

As another example, in association with the command “NOP” in the ninth line, the test pattern memory 106 of the terminal CH1 may store the pattern compression information CODEH1 that does not have the specified value, and the test pattern memories 106 of the terminals CH2, CH3, and CH4 may each store the test pattern sequence and pattern compression information having the specified value.

With the storage format of the test program described above, independent determinations can be made as to whether a test pattern sequence itself, with a large amount of data, is stored or whether predefined pattern compression information is stored instead, in association with the same command. Therefore, the data amount of the program can be efficiently decreased.

More specifically, a first test pattern memory 106 corresponding to a first terminal of the DUT 100 may store one test pattern sequence in association with one command, and a second test pattern memory 106 corresponding to a second terminal of the DUT 100 may store pattern compression information including one piece of predefined pattern identification information in association with this one command. In this case, a first pattern memory reading section 200 corresponding to a first terminal of the DUT 100 reads the one test pattern sequence and the pattern compression information with the specified value stored in the first test pattern memory 106 in association with the one command. Furthermore, a second pattern memory reading section 200 corresponding to a second terminal reads one piece of pattern compression information that does not have a specified value and that is stored in the second test pattern memory 106 in association with the one command.

Next, a second predefined pattern reading section 210 corresponding to the second terminal reads one predefined pattern sequence stored in the predefined pattern memory 118 in association with the one piece of pattern compression information that does not have the specified value. A first channel pattern generating section 140 and driver 170 corresponding to the first terminal output the one test pattern sequence read from the first test pattern memory 106 to the first terminal during the command cycle period in which the one command is executed. Furthermore, a second format control section 144 and driver 170 corresponding to the second terminal output the one predefined pattern sequence read by the second predefined pattern reading section 210 to the second terminal during the command cycle period in which the one command is executed.

The test module 10 described above can increase the chances that a test program can be compressed by storing pattern compression information, which designates predefined pattern identification information or a test pattern sequence for each test pattern memory 106, independently for each terminal, according to the same command.

FIG. 4 is used to describe an example in which the test pattern sequences are stored in the test pattern memories 106, but the same process can be used to store expected value pattern sequences in the expected value pattern memories 108, and therefore a separate description is omitted.

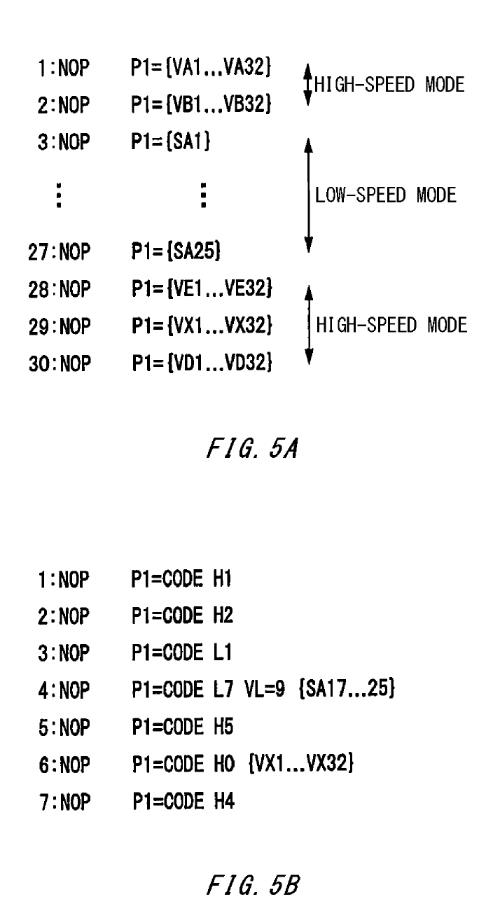

FIG. 5 shows a compression format of a test program according to the present embodiment. FIG. 5A shows a test program before compression. The test program causes the test module 10 to operate in the first operational mode, i.e. the high-speed mode, in lines 1, 2, and 28 to 30, during which the test module 10 outputs a test pattern sequence with 32 patterns for each command cycle. In lines 3 to 27, the program causes the test module 10 to operate in the second operational mode, i.e. the low-speed mode, during which the test module 10 outputs one pattern for each command cycle.

FIG. 5B shows the test program after compression. In the test program, the test pattern sequence {VA1 . . . VA32} prior to compression is stored in the predefined pattern memory 118 as the predefined pattern sequence corresponding to the predefined pattern identification information H1. The test pattern sequence {VA1 . . . VA32} prior to compression is replaced by the pattern compression information CODEH1 designating the predefined pattern identification information H1, and is then stored in the test pattern memory 106. In the same manner, the test pattern sequences {VB1 . . . VB32}, {VD1 . . . VD32}, and {VE1 . . . VE32} prior to compression are respectively replaced by the pieces of pattern compression information CODEH2, CODEH4, and CODEH5 designating the pieces of predefined pattern identification information H2, H4, and H5, and are then stored in the test pattern memory 106.

The test pattern sequence {SA1 . . . SA16} output sequentially according to 16 continuous commands in the second operational mode is stored in the predefined pattern memory 118 as the predefined pattern sequence of the second operational mode corresponding to the predetermined pattern identification information Ll. Furthermore, the test pattern sequence {VX1 . . . VX32} prior to compression is stored in the test pattern memory 106 in a group with the pattern compression information CODEH0 having the specified value of 0000 for the first to fourth bits. In the same manner, the test pattern sequence {SA17 . . . SA25} prior to compression including 9 patterns is stored in the test pattern memory 106 in a group with the pattern compression information CODEL7 having the specified value of 1111 for the first to fourth bits and values indicating 9 for the fifth to eighth bits.

With the test program compression method described above, the test module 10 can store test pattern sequences that are output frequently in the predefined pattern memory 118 as predefined pattern sequences. As a result, the test module 10 can replace many test pattern sequences included in a test program with pattern compression information designating the predefined pattern sequences, thereby efficiently decreasing the size of the test program.

FIG. 5 is used to describe an example in which test pattern sequences are stored in the test pattern memory 106, but expected value pattern sequences can be stored in the expected value pattern memory 108 in the same way, and therefore a separate description is omitted.

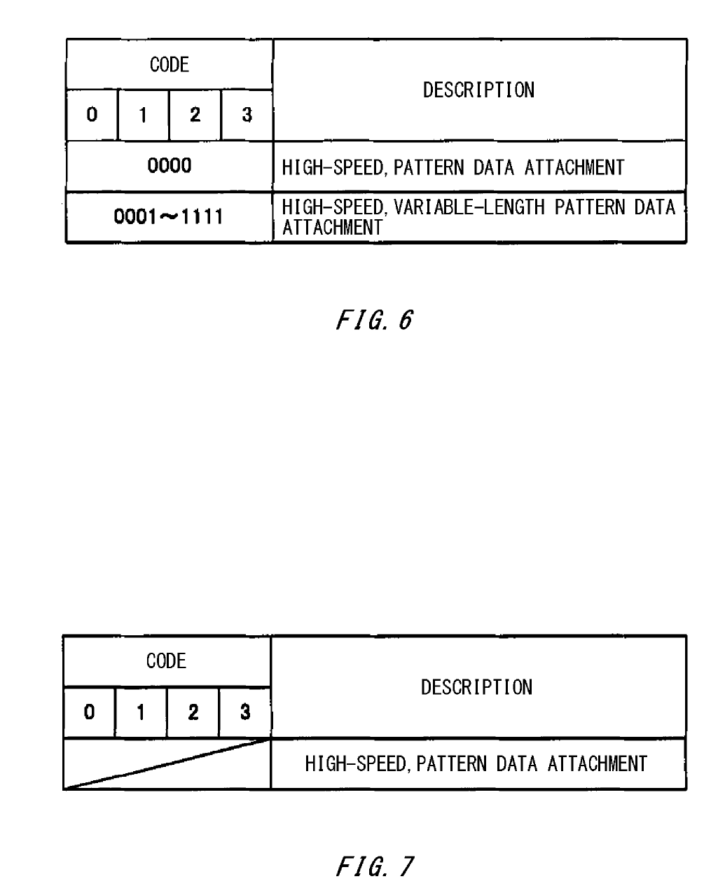

FIG. 6 shows exemplary pattern compression information according to a modification of the present embodiment. In the pattern compression information shown in FIG. 6, the high-speed mode is designated by each code of the compression information. With this pattern compression information, the number of predefined patterns that can be used in the high-speed mode can be increased.

FIG. 7 shows exemplary pattern compression information according to another modification of the present embodiment. In the pattern compression information shown in FIG. 7, a desired pattern sequence is designated by each of the codes of the compression information. With this pattern compression information, null data is allocated as a four-bit portion of compression code, i.e. a four-bit portion of the compression code is deleted, thereby increasing the compression rate. Information indicating if all of the codes designate the high-speed mode or if all of the codes designate desired pattern sequences can be stored in the pattern information memory.

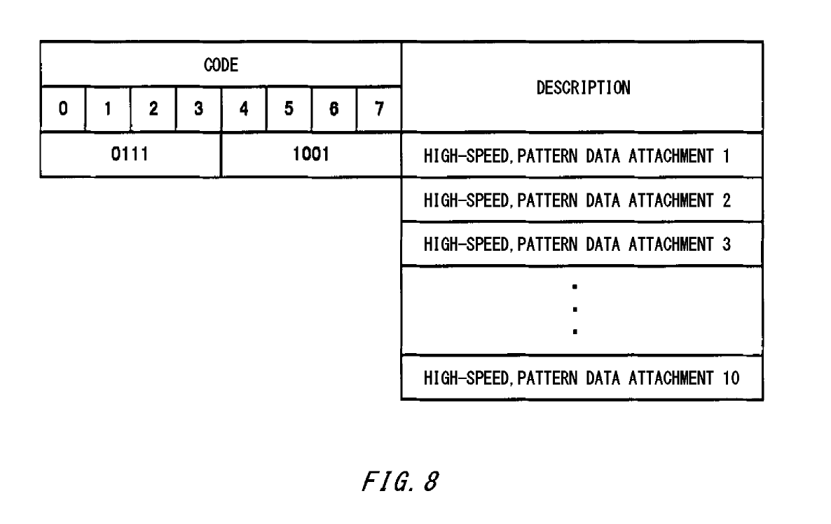

FIG. 8 shows exemplary pattern compression information according to another modification of the present embodiment. In the pattern compression information shown in FIG. 8, eight bits are allocated as the compression information code, and the four most significant bits, which are 0111 in this case, designate the pattern sequence to include a plurality of desired pattern sequences. Furthermore, the four least significant bits, which are 1001 in this case, designate the number of desired pattern sequences. In other words, the compression information can include repetition information that designates the number of times a pattern sequence is repeated. The value 1001 of the four least significant bits indicates that the desired pattern sequence is repeated ten times. With this pattern compression information, the compression information codes in the pattern sequence data from the second repetition onward can be eliminated, thereby increasing the compression rate of the pattern sequence data.

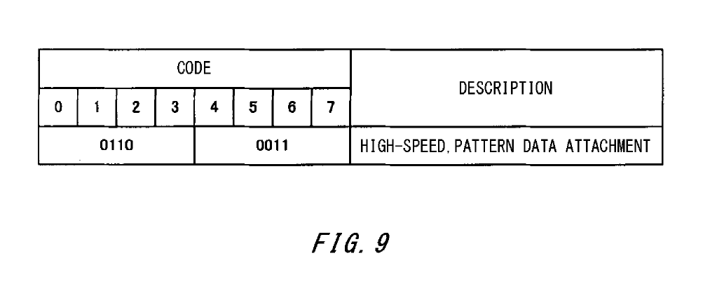

FIG. 9 shows exemplary pattern compression information according to another modification of the present embodiment. In the pattern compression information shown in FIG. 9, eight bits are allocated as the compression information code, and the four most significant bits, which are 0110 in this case, designate that the same pattern sequence is to be repeated. Furthermore, the four least significant bits, which are 0011 in this case, designate the number of repetitions. In other words, the compression information includes repetition information that designates the number of times the pattern sequence is repeated. The value of 0011 for the lowest four bits indicates that the desired pattern sequence is repeated five times. With this pattern compression information the compression information codes in the pattern sequence data from the second repetition onward can be eliminated, thereby increasing the compression rate of the pattern sequence data.

The compression information of FIG. 9 can be designated for each input or output channel. Therefore, the number of repetitions can be designated for each channel even when a different number of repetitions are to be set for the input channels and the output channels, which cannot be achieved using the repeating command IDXI. As a result, the compression rate can be increased. FIG. 9 shows an example in which a desired pattern sequence is used as the repeating pattern sequence, but a predefined pattern sequence can obviously be used instead.

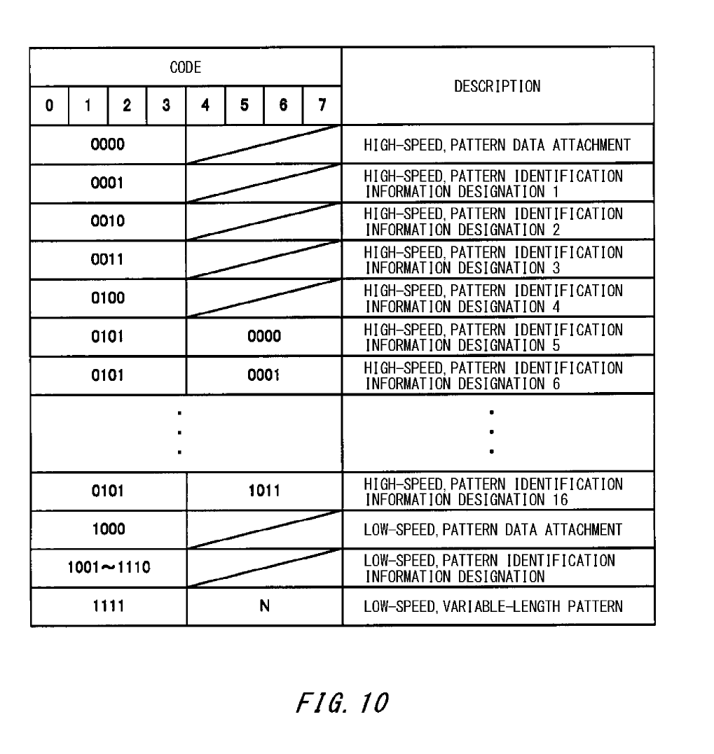

FIG. 10 shows exemplary pattern compression data according to another modification of the present embodiment. In the pattern compression information shown in FIG. 10, eight bits are allocated as the compression information code designating the high-speed mode, and are separated into a pattern sequence designated by only the four most significant bits and a pattern sequence designated by eight bits including the four most significant and four least significant bits. In other words, in addition to storing a high-speed mode pattern sequence as the pattern sequence included in the compression information, short-bit pattern sequence identification information that can designate one address space or long-bit pattern sequence identification information that can designate an address space larger than the one address space is stored as the pattern sequence identification information. Predefined pattern sequences that are used frequently and defined in advance are allocated as the pattern sequences identified by the short-bit pattern sequence identification information. Predefined pattern sequences that are used less frequently than the frequent predefined pattern sequences and defined in advance are allocated as the pattern sequences identified by the long-bit pattern sequence identification information. With this pattern compression information, frequent predefined pattern sequences are designated by four-bit compression information codes and infrequent predefined patterns are designated by eight-bit compression information codes. Accordingly, the overall compression rate can be increased. The compression codes in the high-speed mode are the same as those described above, and therefore a separate description is omitted.

As described above, the test module 10 of the present embodiment can increase the compression efficiency of a test program by independently compressing, for each terminal of a DUT 100, the pattern sequences stored in a plurality of test pattern memories 106 and/or expected value pattern memories 108 for a single command. By more efficiently compressing the test program, the test module 10 can decrease the average data amount read from the test pattern memories 106 and/or expected value pattern memories 108 for each command, thereby keeping the request throughput of the main memory 102 relatively low.

While the embodiments of the present invention have been described, the technical scope of the invention is not limited to the above described embodiments. It is apparent to persons skilled in the art that various alterations and improvements can be added to the above-described embodiments. It is also apparent from the scope of the claims that the embodiments added with such alterations or improvements can be included in the technical scope of the invention.

The operations, procedures, steps, and stages of each process performed by an apparatus, system, program, and method shown in the claims, embodiments, or diagrams can be performed in any order as long as the order is not indicated by “prior to,” “before,” or the like and as long as the output from a previous process is not used in a later process. Even if the process flow is described using phrases such as “first” or “next” in the claims, embodiments, or diagrams, it does not necessarily mean that the process must be performed in this order.

### LIST OF REFERENCE NUMERALS

10 test module
100 DUT
102 main memory
104 command memory
106 test pattern memory
108 expected value pattern memory
110 digital capture memory
112 central pattern control section
114 pattern list memory
116 vector generation control section
118 predefined pattern memory
120 central capture control section
122 pattern result memory
130 channel block
140 channel pattern generating section
142 sequential pattern generating section
144 format control section
146 sequential pattern generating section
148 hunt/compare section
150 fail capture control section
152 fail capture memory
160 timing generating section
170 driver
180 comparator
200 pattern memory reading section
210 predefined pattern reading section
220 pattern selecting section
230 selecting section

What is claimed is:

1. A test module comprising:
a compression information storage section that stores a plurality of pieces of compression information that each associate a pattern sequence with a piece of pattern sequence identification information identifying the pattern sequence;
a basic pattern storage section that stores, as a group of basic patterns, a plurality of pieces of pattern sequence data that each include the pattern sequence or the pattern sequence identification information in association with a command;
an instruction information storage section that stores instruction information indicating a processing order for the basic patterns;
a selecting section that selects, from among the pieces of compression information stored in the compression information storage section, compression information to be used for the basic pattern to be processed according to the processing order indicated by the instruction information;
a basic pattern reading section that reads, from the basic pattern storage section, the pattern sequence data included in the basic patterns to be processed;
a pattern sequence reading section that, when the pattern sequence identification information is included in the pattern sequence data read by the basic pattern reading section, references the compression information selected by the selecting section and reads the pattern sequence corresponding to the pattern sequence identification information; and
a pattern output section that outputs the pattern sequence corresponding to the pattern sequence identification information read by the pattern sequence reading section or the pattern sequence included in the pattern sequence data read by the basic pattern reading section.

2. The test module according to claim 1, further comprising a basic pattern information storage section that stores, in association with each basic pattern, compression information identification information identifying compression information to be used for processing the basic pattern, wherein
the selecting section references the compression information identification information to select the compression information.

3. The test module according to claim 2, wherein
the compression information storage section stores the compression information further including repetition information that designates the number of times each pattern sequence is repeated, and
the pattern output section repeatedly outputs each pattern sequence according to the number of repetitions designated by the repetition information.

4. The test module according to claim 3, wherein
the compression information storage section stores, as each pattern sequence, the compression information including a desired pattern sequence that is designated for each piece of compression information or a predefined pattern sequence determined in advance.

5. The test module according to claim 4, wherein
the compression information storage section includes a plurality of the desired pattern sequences as the pattern sequences and stores, as the repetition information designating the number of desired pattern sequences, a single piece of pattern sequence identification information identifying the entirety of the desired pattern sequences, and
the pattern output section outputs the number of desired pattern sequences designated by the repetition information.

6. The test module according to claim 1, wherein
the compression information storage section stores, as the compression information, the pattern sequence and the pattern sequence identification information for each input or output channel, and
the pattern output section outputs the pattern sequence for each channel.

7. The test module according to claim 1, wherein
the compression information storage section stores high-speed mode pattern sequences or low-speed mode pattern sequences as the pattern sequences and stores, as the pattern sequence identification information, pattern identification information indicating whether the corresponding pattern sequence is a high-speed mode pattern sequence or a low-speed mode pattern sequence.

8. The test module according to claim 7, wherein
the compression information storage section stores the high-speed mode pattern sequences as the pattern sequences included in the compression information and stores, as the pattern sequence identification information, short-bit pattern sequence identification information that can designate one address space or long-bit pattern sequence identification information that can designate an address space larger than the one address space,
a frequent predefined pattern sequence that is determined in advance and used frequently is allocated as a pattern sequence identified by the short-bit pattern sequence identification information, and
an infrequent predefined pattern sequence that is determined in advance and used less frequently than the frequent predefined pattern sequence is allocated as a pattern sequence identified by the long-bit pattern sequence identification information.

9. The test module according to claim 7, wherein
the compression information storage section stores a desired pattern sequence that is determined for each piece of compression information and is a high-speed mode pattern sequence as all of the pattern sequences included in the compression information, and stores null data as the pattern sequence identification information.

10. A test apparatus comprising:
a compression information storage section that stores a plurality of pieces of compression information that each associate a pattern sequence with a piece of pattern sequence identification information identifying the pattern sequence;
a basic pattern storage section that stores, as a group of basic patterns, a plurality of pieces of pattern sequence data that each include the pattern sequence of the pattern sequence identification information in association with a command;
an instruction information storage section that stores instruction information indicating a processing order for the basic patterns;
a selecting section that selects, from among the pieces of compression information stored in the compression information storage section, compression information to be used for the basic patterns to be processed according to the processing order indicated by the instruction information;
a basic pattern reading section that reads, from the basic pattern storage section, the pattern sequence data included in the basic patterns to be processed;
a pattern sequence reading section that, when the pattern sequence identification information is included in the pattern sequence data read by the basic pattern reading section, references the compression information selected by the selecting section and reads the pattern sequence corresponding to the pattern sequence identification information; and
a pattern output section that outputs the pattern sequence corresponding to the pattern sequence identification information read by the pattern sequence reading section or the pattern sequence included in the pattern sequence data read by the basic pattern reading section.

11. A test method comprising:
compression information storage of storing a plurality of pieces of compression information that each associate a pattern sequence with a piece of pattern sequence identification information identifying the pattern sequence;
basic pattern storage of storing, as a group of basic patterns, a plurality of pieces of pattern sequence data that each include the pattern sequence of the pattern sequence identification information in association with a command;
instruction information storage of storing instruction information indicating a processing order for the basic patterns;
selecting, from among the pieces of compression information stored during the compression information storage, compression information to be used for the basic patterns to be processed according to the processing order indicated by the instruction information;
basic pattern reading of reading the pattern sequence data included in the basic patterns to be processed;
pattern sequence reading of, when the pattern sequence identification information is included in the pattern sequence data read during the basic pattern reading, referencing the selected compression information and reading the pattern sequence corresponding to the pattern sequence identification information; and
pattern output of outputting the pattern sequence corresponding to the pattern sequence identification information read during the pattern sequence reading or the pattern sequence included in the pattern sequence data read during the basic pattern reading.
